(19) United States
(12) Patent Application Publication
(10) Pub. No.: US 2006/0240199 A1
(43) Pub. Date: Oct. 26, 2006

(54) Pellicle frame

(76) Inventor: Kazutoshi Sekihara, Annaka-shi (JP)

Correspondence Address: LOWE HAUPTMAN BERNER, LLP, 1700 DIAGONAL ROAD, SUITE 300, ALEXANDRIA, VA, 22314, US

(21) Appl. No.: 11/368,394

(22) Filed: Mar. 7, 2006

(30) Foreign Application Priority Data
Apr. 25, 2005 (JP) JP2005-126736

(51) Int. Cl. G03F 1/14

(52) U.S. Cl. 428/14; 428/131

(57) ABSTRACT

The invention provides a pellicle frame which can readily be peeled off after being adhesively attached to a photomask, and a photolithographic framed pellicle which makes use of this pellicle frame. The pellicle frame provided by the invention is a rectangular framework body of which the longer side framework member has a length of at least 500 mm, wherein at least one cavity is provided on the outside surface of any framework member at a distance of 50 mm or smaller from a corner of the frame. It is preferable that at least five cavities are provided on the outside surfaces of the pellicle frame, and the cavities each have a cylindrical configuration having a diameter in the range from 1.0 mm to 3.0 mm and a depth of at least 0.5 mm, but not deep enough to penetrate the framework member through. The framed pellicle is constructed by using this pellicle frame.

### BACKGROUND OF THE INVENTION

The present invention relates to a frame for a photolithographic framed pellicle used for shielding against dust in the manufacture of semiconductor devises, printed circuit boards, liquid crystal display panels, and others, and more particularly relates to a frame for a large-size pellicle frame used in the manufacture of liquid crystal display panels.

In the manufacture of liquid crystal display panels, semiconductor devices such as LSIs, and the like, a pattern is produced by irradiation with light at a semiconductor wafer or base glass plates for liquid crystal use, but if any dust particles should be deposited to the photomask (sometimes called a reticle) used here (hereinafter referred to as a “photomask”), the dust particles will scatter or deflect the light. This trouble is a problem because the transferred pattern lose fidelity.

For this reason, the patterning work is usually performed in a clean room, but even then it is difficult to keep the photomask clean at all times. This is handled by applying a pellicle as a dust shield to the photomask surface.

In this case, dust particles will not be deposited directly onto the surface of the photomask, but onto the pellicle membrane instead, so that, if the focusing in the course of photolithographic patterning is on the pattern of the photomask, any dust particles on the pellicle membrane will not affect the fidelity of patterning.

These pellicles are usually prepared by using a transparent pellicle membrane made from a plastic resin such as nitrocellulose, cellulose acetate, fluorocarbon resins and the like having good transparency to the light, coating the top face of a pellicle frame made of aluminum, stainless steel, polyethylene, or the like with a good solvent of the resin of the film, and then air drying the coating and bonding the pellicle film to the top face (see Japanese Laid-Open Patent Application S58-219023), or by bonding with an acrylic resin, epoxy resin, or other adhesive agent (see U.S. Pat. No. 4,861,402 or Japanese Patent Publication S63-27707), and a pressure-sensitive adhesive layer composed of a polybutene resin, polyvinyl acetate resin, acrylic resin, or the like and used for mounting to a photomask, and a release layer (releasable separator) for protection of the pressure-sensitive adhesive layer, are further provided to the bottom surface of the pellicle frame.

Also, small openings for adjusting the air pressure are sometimes formed in the pellicle frame, and a filter is provided for preventing intrusion of dust particles from the atmospheric air that moves through the openings, the purpose of which is to eliminate the air pressure differences between the outside and the space surrounded by the pellicle in a state in which the pellicle has been applied to the photomask (see Japanese Patent Publication S63-393703).

In the preparation of a framed pellicle, the pellicle frame must be supported for assembly and transportation, and as shown in FIG. 6, a groove or cavity 63 is usually provided to the outer surface of the pellicle frame, and a pin or the like is inserted into this groove or cavity to support the frame. It is usual that two cavities are provided on each of two positions on each of the two opposing side framework members, for a total of four cavities. The cavities 63 here are often provided at positions apart from the corners 62 by about 20 to 30% of the length of one side member of the frame, so that there will be smaller bending in the vertical direction when the pellicle frame is supported by pins or the like.

Once attached to a photomask, the pellicle may have to be peeled off and reattached for some reasons. In such a case, reattaching of the pellicle is conducted by a method in which a plate-form tool is inserted into the photomask pressure-sensitive adhesive layer and the frame is lifted and peeled off, or, as shown in FIGS. 5A and 5B, a method in which a pin-formed tool 54 is inserted into a cavity 52 provided in the outer surface of the pellicle frame and the pellicle frame 51 is lifted and peeled off by utilizing the principle of leverage, for example.

When a plate-form tool is thrust into the photomask adhesive layer, it can be thrust all the way around the pellicle frame, which is an advantage in that the peeling can be started at an end position of the easiest peeling, but this is not necessarily desirable because of the risk of damaging the photomask.

On the other hand, this risk is reduced in a method in which a pin-formed tool is inserted into the cavity provided in the outer surface of the pellicle frame. However, the cavities are provided usually only at four positions, as mentioned above, and those positions are selected without taking into account their service for peeling of the framed pellicle. Consequently, a drawback there is that, with a large-size pellicle having 500 mm or larger length on one side, a large surface area has to be peeled all at once so that an extremely high force is required for peeling.

A problem in the use of a peeling tool like those mentioned above is that, while the pellicle frame is warped to be lifted up for peeling during thrusting of the peeling tool, the frame returns back to its bonded disposition when the peeling tool is removed to be once again in an adhesively bonded condition from which a great difficulty is encountered in trying peeling once again.

### SUMMARY OF THE INVENTION

The present invention was conceived in view of the above problems, and the object thereof is to provide a large pellicle frame which affords easy peeling after mounting onto a photomask, and a photolithographic pellicle by making use of this pellicle frame.

The present invention for solving the above problems provides a pellicle frame of a large pellicle of which the longer side members of the framework have a length of at least 500 mm, wherein among others at least one cavity is provided on the outer side surface of either a longer or a shorter side framework member at a position apart from the corner by a distance of 50 mm or smaller.

In particular, the distance between the cavity and the corner of the generally rectangular frame work mentioned above is defined to be the distance between the center of the cavity and the nearest intersection of the extensions of the outer surfaces of the longer side framework members and the shorter side framework members.

It is preferable that at least five cavities are provided on the outer surface of the framework members, and the cavities each have a cylindrical configuration with a diameter in the range from 1.0 mm to 3.0 mm and a depth of at least 0.5 mm, but not deep enough to penetrate the framework member.

The present invention also provides a framed pellicle constructed with the above described inventive pellicle frame.

In the present invention, even with a large pellicle having a length of 500 mm or larger on the longer side, if a cavity is provided at a position apart from the corner by 50 mm or smaller, then the peeling of the pellicle from the photomask surface can be started at the end that is at the corner, so that peeling requires smaller force, and the pellicle frame in the vicinity of the corner will be warped upwardly and plastically deformed starting at the vicinity of the corner inward, rendering the adhesive re-bonding less likely to occur enabling very easy peeling.. Also, if a cavity disposed in some other positions not in the vicinity of a corner is used, then peeling can proceed little by little even for a particularly large pellicle having a 500 mm or larger length on one side, which renders peeling much easier.

### BRIEF DESCRIPTION OF THE DRAWING

FIG. 1 is an illustration of an inventive pellicle frame by a plan view and a side view;

FIG. 2 is an illustration of an inventive pellicle frame as lifted up from a glass substrate;

FIG. 3 is a partial cross sectional view of a framed pellicle with an inventive pellicle frame showing a cavity provided in the frame according to the present invention;

FIG. 4A is an illustration of another embodiment of the inventive pellicle frame;

FIG. 4B is an illustration of a still different embodiment of the inventive pellicle frame;

FIGS. 5A and 5B are each an illustration of the starting manner for the removal of the framed pellicle according to the invention from a substrate plate by using a peeling lever;;

FIG. 6 is an illustration of a conventional pellicle frame; and

FIG. 7 is an illustration of a conventional framed pellicle under a procedure of peeling from a substrate.

### DETAILED DESCRIPTION OF THE PREFERRED EMBODIMENTS

Embodiments of the present invention will now be described by making reference to the drawings, but the present invention is never limited to or by these embodiments.

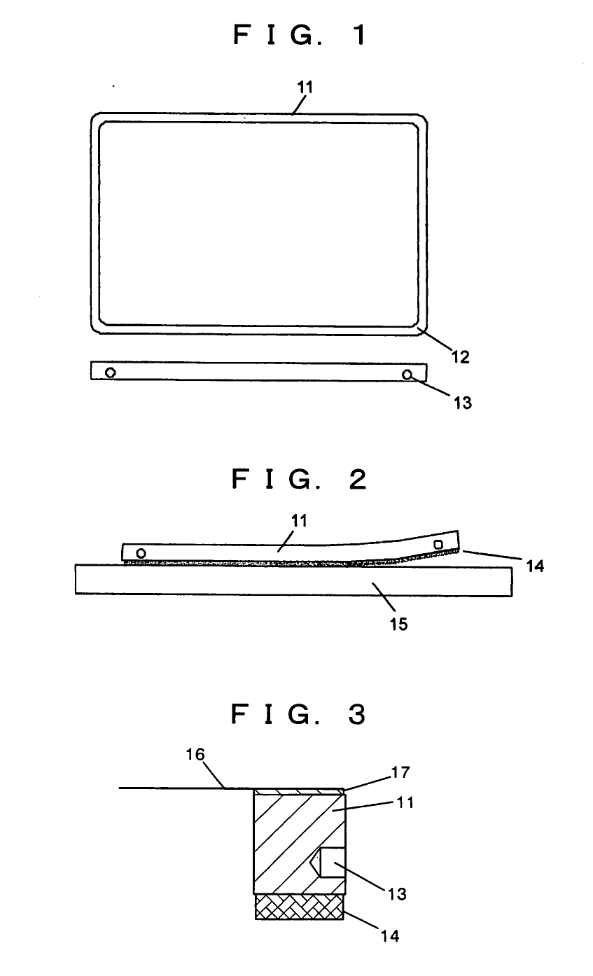

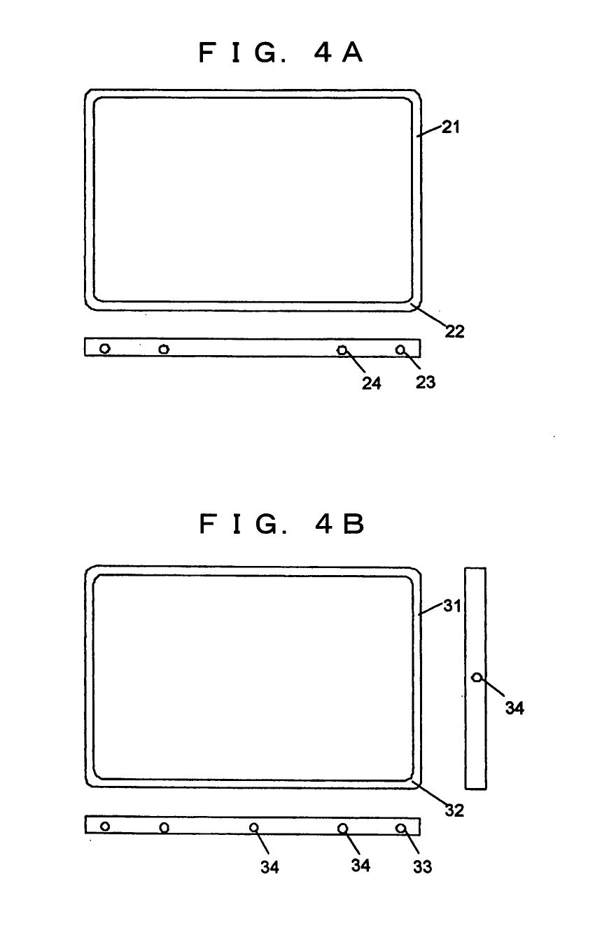

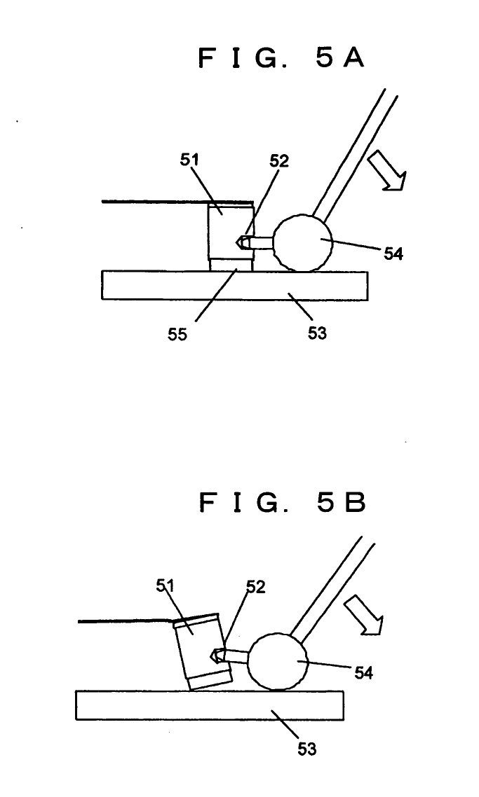

FIG. 1 is an illustration of an embodiment of the pellicle frame according to the present invention, FIG. 2 is a schematic illustration of the state when the pellicle frame according to the present invention has been peeled off from a glass substrate, FIG. 3 is a cross sectional view showing a cavity provided in the pellicle frame according to the present invention, FIG. 4A is an illustration of another embodiment of the pellicle frame according to the present invention, FIG. 4B is an illustration of a still different embodiment of the pellicle frame according to the present invention, FIG. 5A is a schematic illustration of the state when a pellicle is peeled off with a peeling lever, and shows the state at the start of peeling, and FIG. 5B is a simplified illustration of the state when a pellicle is peeled off with a peeling lever, and shows the state after proceeding of the peeling procedure.

In FIG. 1, cavities 13 are provided closely to (by a distance of 50 mm or smaller from) the corners 12 on the longer side framework members of the pellicle frame 11.

Accordingly, when a pin or the like peeling tool is thrust into this cavity 13 and to lift up the pellicle frame, since the peeling process is started from the corner as shown in FIG. 2, the peeling requires a smaller force, and the pellicle frame near the corner will be plastically deformed upward, making re-adhesion less likely to occur and rendering the peeling procedure very easy. However, the positions of these cavities 13 must be apart from the corner 12 by a distance not exceeding 50 mm; if peeling is performed beyond that, there will be a marked increase in the force required by the peeling, and it will be difficult to completely peel off the corners, so that the desired effect cannot be obtained.

It is the prior art that these cavities are provided by twos on the respective opposite framework members in view of the purpose of supporting the framed pellicle, with emphasis on balancing the load, and were therefore generally provided in four positions, but, in the present invention, in addition to the cavities intended to support the pellicle frame, either an additional cavity is disposed at a position that takes peeling into consideration, or only a cavity that takes peeling into consideration is disposed, the result being that peeling can be performed more easily.

Furthermore, the cavities here preferably have a diameter of at least 1.0 mm but not larger than 3.0 mm and a depth of at least 0.5 mm, and are each a cylindrical cavity not deep enough to penetrate the framework through. Since conventional cavities are focused to the service of supporting, all that mattered is that the supporting device can be engaged, and the diameter and depth are not necessarily engageable with a peeling tool.

If a pellicle is constituted by using a pellicle frame such as this, it will be very easy to remove the pellicle from the photomask on which it is mounted with intervention of a pressure-sensitive adhesive layer.

In this embodiment, the cavities 13 are disposed near the corners 12 on the longer side members of the framework, but instead can be disposed on the shorter sides. Alternatively, they can be provided on all of the longer sides and the shorter sides (FIG. 4B). Further, cavities can be provided for supporting the pellicle frame, and some other cavities can be provided to serve for peeling (FIG. 4A).

FIG. 3 is a cross sectional view of the preferable shape of the cavities, and basically the configuration of the cavity is generally cylindrical. A cylindrical form of the cavity ensures easier machining works, and also ensures a better fitting with cylindrical pins commonly under use. Also, when a good fitting with the pins used for supporting the peeling tool is taken into consideration, the depth should preferably be at least 0.5 mm.

The diameter of the cavity should be at least 1 mm but not larger than 3 mm, with a range of 2 to 2.5 mm being particularly preferable. If the diameter is smaller than 1 mm, it will be difficult to ensure a sufficient strength of the pins used for supporting or peeling, and it will be difficult to satisfy the strength required in accurate supporting or peeling. If the diameter is larger than 3 mm, on the other hand, a considerable portion of the frame member is lost to cause a problem of insufficient strength of the frame during use, and the area around the cavities may become turned up or chipped off during peeling so that the difficulty in peeling of the pellicle is increased. Also, as shown in the drawings, the bottom form of the cylindrical cavity can be left conical as formed by the drill tip, or can be finished to have a semispherical surface, flat surface, or the like.

Working is usually more simple if the size and shape of all of the cavities are identical, but the cavities may have individually different sizes and forms optimized by taking into consideration the particular purposes of the respective cavities..

FIG. 4A shows another embodiment, in which a pair of other cavities 24 are provided between another pair of cavities 23 positioned close to the corners 22. In FIG. 4B, additional cavities 34 are provided not only on the longer side members of the framework, but also on the shorter side members. With such an arrangement of cavities, even in a particularly large pellicle frame having a length of 700 mm or larger for the longer side, pins can be successively inserted into the cavities first at the corner and the pellicle is gradually peeled so as to ensure easy peeling of the framed pellicle off the photomask.

As is described above, in the present invention, cavities are provided close to the corner of a generally rectangular framework at a position considerably outwardly deviated from the position as set by taking into consideration the downward warping of the framework member. Accordingly, downward warping by gravity is to be expected when the pellicle frame is supported by a pin, but this can be prevented by supporting the pellicle frame at four or more cavities as in these embodiments. This can also be compensated for by providing a support from below to the manufacturing machine side.

### EXAMPLE 1

An example of the present invention will now be described, but the present invention is never limited to or by this Example.

A pellicle frame 11 of an aluminum alloy was prepared by machining in the shape shown in FIG. 1. This pellicle frame 11 had a generally rectangular form with outer dimensions of 782×474 mm, inner dimensions of 768×456 mm, and a height of 5 mm. The cavities 13 here were disposed at a total of four positions on the opposite sides and 36 mm apart from the corners 12 on the longer side framework members. The diameter thereof was 2.5 mm and the depth was 2.5 mm, not sufficiently deep to penetrate the frame, the cavities each having a cylindrical configuration.

This pellicle frame was washed and dried, followed by coating of one end surface with a silicone-based pressure-sensitive adhesive to serve as a pellicle film adhesive, and the other end surface was coated with the same silicone-based pressure-sensitive adhesive (KR120, trade name by Shin-Etsu Chemical Co.) as a 50% dilution with toluene to serve as a photomask adhesive. The adhesive layers were cured by heating.

An about 4 μm thick pellicle membrane of a fluorocarbon resin was prepared by spreading a coating solution of the resin (Cytop, a tradename by Asahi Glass Co.) over a 8 mm thick, 800 mm by 920 mm wide quartz glass plate by spin coating followed by drying. The adhesive-coated frame was placed on this substrate-supported pellicle membrane after trimming away of extraneous portions and adhesively bonded thereto to form a framed pellicle which was removed from the quartz glass plate by peeling.

As shown in FIG. 5A, this completed pellicle 51 was attached onto a smooth quartz glass substrate 53 (520×800×8 mm thick) by pasting under a load of 120 kg, and then a peeling tool 54 was inserted into a cavity 52, and a peeling test was made to remove the framed pellicle from the quartz glass plate 53.

As a result, the peeling work with the peeling tool 54 allowed the frame to be peeled off at the corner portion in the form shown in FIGS. 2 and 5B. This peeling work was repeated for the cavities at all of four positions, whereupon only the center part along each side member of the pellicle frame was left unpeeled. Thereafter, the pellicle frame was gripped directly by hand and slowly pulled upward, whereupon it was completely pulled off from the quartz glass plate.

Example 2

A pellicle frame 21 made from an aluminum alloy was prepared by machining in the shape shown in FIG. 4A. This pellicle frame 21 was generally rectangular in shape, and had outer dimensions of 782×474 mm, inner dimensions of 768×456 mm, and a height of 5 mm, just as in Example 1. Cavities were provided at four positions 23 each 36 mm apart from the corner 22 on one of the longer side members, and at four positions 24 each 166 mm apart from the corner 22. Each cavity had a diameter of 2.5 mm and a depth of 2.5 mm, and they were each a cylindrical cavity not deep enough to penetrate through the side member of the framework. The pellicle frame 21 was washed and dried, and then it was worked into a framed pellicle by the same procedure as in Example 1 above.

The thus completed pellicle was adhesively attached onto a smooth quartz glass plate (520×800×8 mm thickness) by pressing under a load of 120 kg, and then a peeling test was made to peel the pellicle off from the quartz glass plate, starting at a point near a corner, in the same manner as in Example 1. As a result, the operation of the peeling tool 54 allowed the pellicle frame to be easily lifted up. Thereafter, the same working procedure was repeated for each of the adjacent cavities successively, whereupon the pellicle frame as a whole could be completely peeled off once but then a part of it came back into contact to be in an adhesively bonded condition, though very lightly. Thereafter, the pellicle frame was gripped directly by hand and slowly pulled up, whereupon it could be easily pulled apart from the quartz glass substrate.

Comparative Example

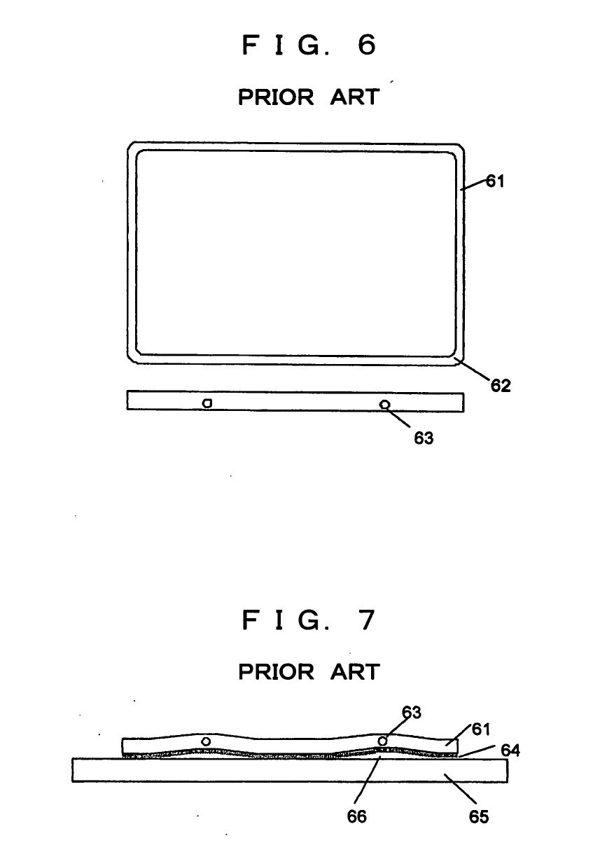

A pellicle frame 61 made from an aluminum alloy was prepared by machining in the shape shown in FIG. 6. This pellicle frame 61 was rectangular in form, and had outer dimensions of 782×474 mm, inner dimensions of 768×456 mm, and a height of 5 mm, just as in Example 1. The cavities 63 here were disposed at four positions each 170 mm apart from a corner 62 on the longer side framework member. The diameter thereof was 2.5 mm and the depth was 2.5 mm, and each cavity was a cylindrical cavity not deep enough to penetrate the framework member through. After cleaning by washing and drying, the pellicle frame was worked in the same manner as in Example 1 into a framed pellicle.

The thus completed pellicle was adhesively attached onto a quartz glass plate and a trial was made to peel the framed pellicle off, in the same manner as in Example 1. The result was that, in addition to the requirement of a very large force for lifting of the framed pellicle with appearance of a gap 65, as is shown in FIG. 7, no peeling could be effected excepting the regions around the cavities 63. This was the limit with the peeling tool used there for peeling of the pellicle frame giving absolutely no possibility of complete peeling.

In the present invention, in the need to separate a photomask and a framed pellicle adhesively attached to the photomask, they can be separated apart easily, simply, and safely, without necessitating a large peeling force, so that the present invention has very great utilizability in the technological field of photolithography in which framed pellicles are employed.

What is claimed is:

1. A frame for a framed pellicle used in photolithography as a generally rectangular framework made from a rigid material, of which the longer side framework members have a length of at least 500 mm, wherein said frame is provided with one or more cavities on its outer side surfaces, including at least one cavity whose center is at a distance of 50 mm or smaller from an intersection of extensions of outer side surfaces of a longer side framework member and a shorter side framework member.

2. The frame for a framed pellicle as claimed in claim 1 wherein total number of cavities is five or more.

3. The frame for a framed pellicle as claimed in claim 1 or 2 wherein every cavity provided on the outer surface of the framework member has a cylindrical configuration having a diameter in the range from 1.0 mm to 3.0 mm and a depth of at least 0.5 mm but not deep enough to penetrate the framework member through.

4. A framed pellicle used in photolithography which comprises the pellicle frame defined in claim 1 and a pellicle membrane spread over and adhesively bonded to one end surface of the pellicle frame in a slack-free fashion.
